(19) United States
(12) Patent Application Publication
(10) Pub. No.: US 2008/0197490 A1
(43) Pub. Date: Aug. 21, 2008

(54) Conductive structure for a semiconductor integrated circuit and method for forming the same

(75) Inventor: J. B. Chyi, Sinshih Township (TW)

Correspondence Address: BIRCH STEWART KOLASCH & BIRCH, PO BOX 747, FALLS CHURCH, VA, 22040-0747, US

(73) Assignee: CHIPMOS TECHNOLOGIES INC.

(21) Appl. No.: 11/898,613

(22) Filed: Sep. 13, 2007

(30) Foreign Application Priority Data
Feb. 16, 2007 (TW) 096106258

(51) Int. Cl. H01L 23/48; H01L 21/44

(52) U.S. Cl. 257/737; 438/667; 257/E21.476; 257/E23.01

(57) ABSTRACT

A conductive structure for a semiconductor integrated circuit and method for forming the conductive structure are provided. The semiconductor integrated circuit has a pad and a passivation layer partially overlapping the pad to define the first lateral size of the first opening. The conductive structure electrically connects to the pad via the first opening. The conductive structure overlaps the first opening portion and parts of the passivation layer to provide a lower conductive resistance for the pad when connecting to a bump. Meanwhile, the conductive structure provides no discontinuity over the passivation layer in other places, thereby providing a stable conduction.

This application claims priority to Taiwan Patent Application No. 096106258 filed on Feb. 16, 2007, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a conductive structure. More particularly, the present invention relates to a conductive structure for a semiconductor integrated circuit and a method for forming the same.

2. Descriptions of the Related Art

A number of bump electroplating technologies have been developed in the fields of microelectronics and micro systems. Such bump electroplating technologies are applicable to various stages of many processes, such as establishing a connection between a flat panel display and a driver IC, carrying out technologies for conductive lines and air bridges on a gallium arsenide chip, and fabricating X-ray masks when using LIGA technology.

For example, in connecting the circuit board to the IC, the IC may be connected with the circuit board in a variety of ways. Usually, the IC pads of the IC package can be electrically connected to the circuit board using bump (especially gold bump) electroplating technology. Such a technology not only substantially reduces the size of the ICs, but also allows them to be directly embedded into the circuit boards, thus, reducing the space, dissipating the heat and resulting in low induction. In addition, the low cost of the electroplating process has made bump electroplating technology a favorable development.

Typical bump electroplating processes, such as the gold bump electroplating process, require the preparation of an under bump metal on the pads. This under bump metal not only serves as the adhesion layer between the bumps and the pads, but is also typically electrically connected to the conductive layer. Such a conductive layer may be formed independently from or correspondingly to the under bump metal. The conductive layer may also be formed with the same process and material as the under bump metal, so that it can serve as a conductive medium together with the subsequent electroplated bumps. As a result, the bumps can be successfully formed on such an under bump and be electrically connected to the pads therethrough. For this reason, a plurality of conductive layers need to be formed on the chip surface at locations other than the pads prior to the electroplating process and be removed by etching subsequent to the bump electroplating process.

However, in practice, the chip may have a rough surface. In this case, the conductive layer formed on such a rough surface tends to have nonconductive discontinuities or an uneven thickness, which may lead to increased electrical resistance of the conductive layer. As a response, in conventional technologies, the conductive layer and the under bump metal have been formed with a large average thickness to prevent the formation of discontinuities in the conductive layer. However, the increased thickness of the under bump metal inevitably results in an increased equivalent resistance, and since the under bump metal between the bumps and the pads already has a relatively large resistance, a thicker under bump metal will result in increased resistance between the bumps and the pads. As a result, the electrical connection between the chip and the circuit board is unfavorable. All these facts adversely impact the electroplating effect, resulting in a lower yield of the bump electroplating process and a need for refinishing or completely discarding the resulting chip. As a result, it is important to develop a conductive layer without impacting the conductive properties of the under bump metal; such an invention is described below.

### SUMMARY OF THE INVENTION

One objective of this invention is to provide a conductive structure for a semiconductor integrated circuit, wherein the semiconductor integrated circuit comprises a pad and a passivation layer partially overlapping the pad to define a first opening having a first lateral dimension, so that the conductive structure is adapted to electrically connect with the pad through the first opening. The conductive structure overlaps the first opening and a portion of the passivation layer to provide the pad with a conductive layer of lower conductive resistance.

Another objective of this invention is to provide a conductive structure of a semiconductor integrated circuit, wherein the semiconductor integrated circuit comprises a pad and a passivation layer, so as to form a conductive layer free of discontinuities on the passivation layer and to demonstrate stable resistance characteristics.

A conductive structure comprising a first and second conductive layer is provided in this invention. The first conductive layer is formed on the passivation layer and defines the second opening with a second lateral dimension corresponding to the first opening. The second lateral dimension is not smaller than the first lateral dimension. The second conductive layer is formed in the first opening electrical connection to the pad, wherein the second conductive layer continuously overlaps the periphery of both the first conductive layer and passivation layer.

Further disclosed in this invention is a method for forming such a conductive structure on a semiconductor integrated circuit, wherein the semiconductor integrated circuit comprises a pad and a passivation layer partially overlapping the pad to define a first opening having a first lateral dimension. This method comprises the following steps: forming a first conductive layer to define a second opening having a second lateral dimension, which corresponds to the first lateral dimension of the first opening; and forming a second conductive layer in the first opening electrical connection to the pad via the first opening. The second conductive layer overlaps the periphery of both the first conductive layer and passivation layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1(a) to FIG. 1(h) depict schematic views of a process flow for forming a conductive structure of a semiconductor integrated circuit in accordance with a preferred embodiment of this invention.

### DESCRIPTION OF THE PREFERRED EMBODIMENT

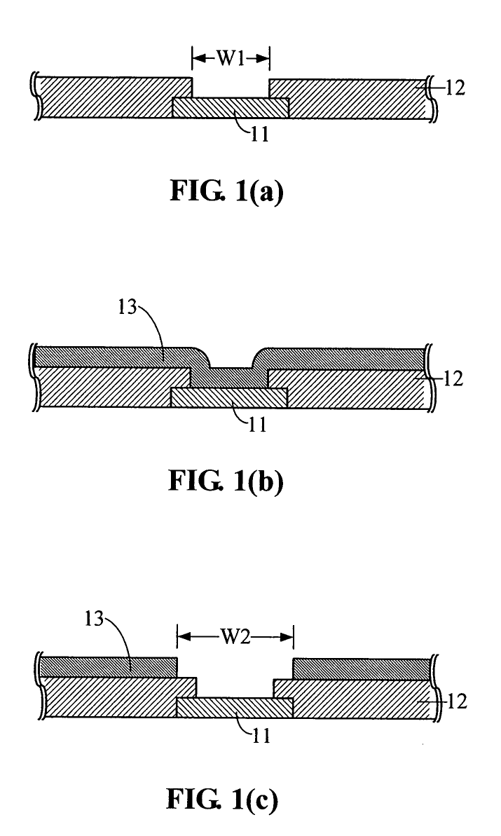

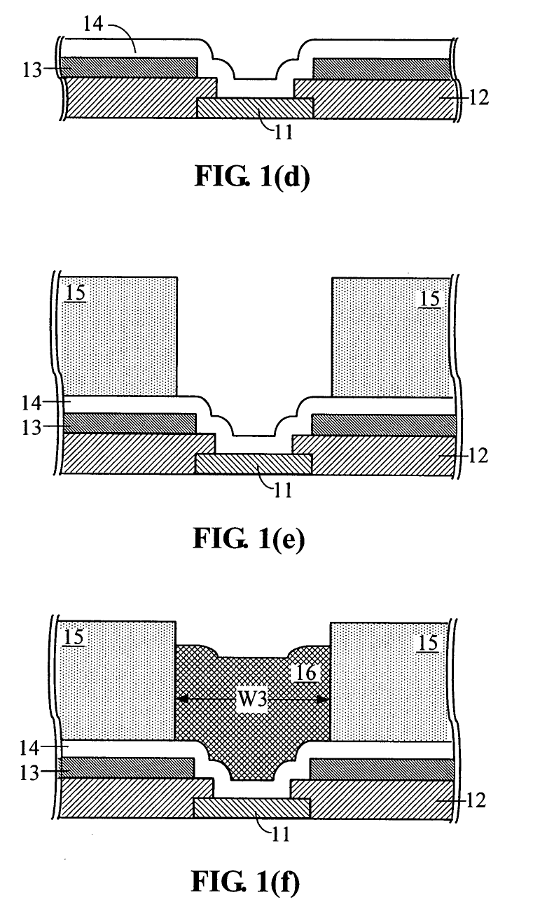

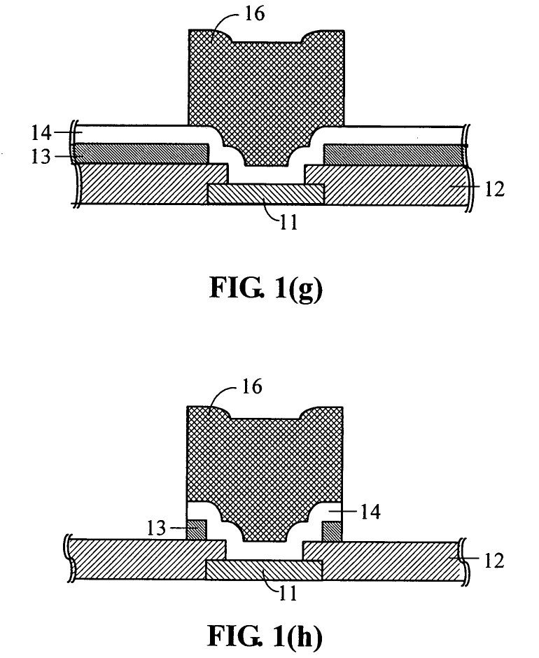

FIG. 1(a) to FIG. 1(h) depict schematic views of a process flow for forming a conductive structure of a semiconductor integrated circuit in accordance with a preferred embodiment of this invention.

FIG. 1(a) depicts the initial step of the fabrication process, which begins with the formation of a pad 11 and a passivation layer 12. In this embodiment, the pad 11 is made of aluminum. The passivation layer 12 partially overlaps the pad 11 so that a portion of the pad 11 is exposed to define a first opening having a first lateral dimension W1. The first opening will be used as a window through which the pad 11 is connected to a bump. Since the passivation layer 12 overlaps the periphery of the pad 11, the lateral dimension of the first opening portion is smaller than that of the pad.

Subsequently, a first conductive layer (e.g., a titanium/tungsten alloy conductive layer 13) is formed and overlaps the first opening portion and extends over the passivation layer 12. As shown in FIG. 1(b), by overlapping the first opening, a concave is naturally formed in the conductive layer 13.

Next, a portion of the titanium/tungsten alloy conductive layer 13 around the first opening portion is removed, for example, by utilizing a conventional exposure and development technology to define a second opening and then removing the unnecessary titanium/tungsten alloy by etching. The second opening overlapping the first opening is formed in the titanium/tungsten alloy conductive layer 13 to selectively expose a portion of the passivation layer 12. Other steps for removing a metal in this embodiment may also be accomplished in this way. As shown in FIG. 1(c), the resulting second opening has a second lateral dimension W2 that is larger than W1, so as to fully expose the first opening. With W2 larger than W1, the first and the second opening portions are adapted to form a stair-shape profile in the passivation layer 12 and the titanium/tungsten alloy conductive layer 13.

Then, the second conductive layer (i.e., an under bump layer), which may also be a titanium/tungsten alloy conductive layer 14, is formed on the titanium/tungsten alloy conductive layer 13 to overlap the first and second openings for electrical connection to the pad 11. As shown in FIG. 1(d), by overlapping the first and second openings, a concave portion naturally appears in the titanium/tungsten alloy conductive layer 14. Since the titanium/tungsten alloy conductive layer 14 is continuously formed to overlap the edges of the first and second openings, a reliable conductive path necessary for subsequent bump formation is provided.

In the structure shown in FIG. 1(d), only a thin titanium/tungsten alloy layer (i.e., the titanium/tungsten alloy conductive layer 14) is formed as the under bump metal in the first opening to electrically connect to the pad. Meanwhile, over the passivation layer, a conductive layer for furnishing a conductive path in the electroplating process is comprised of two titanium/tungsten alloy conductive layers, i.e., the titanium/tungsten alloy conductive layers 13 and 14. Such a thick conductive layer can ensure reliable conduction without the formation of discontinuities even when the chip has a rough surface. Furthermore, the conductive layer provides a stable resistance to facilitate the implementation of the subsequent electroplating step.

A photoresist layer 15 is then coated onto the entire chip surface. The portion thereof where a bump is to be formed is removed to form a space, as shown in FIG. 1(e).

Subsequently, a bump 16 is formed by electroplating to overlap and electrically connect to the titanium/tungsten alloy conductive layer 14 over the first and the second openings, as shown in FIG. 1(f). In this embodiment, the bump 16 is made of gold, and has a third lateral dimension W3 which is larger than W2, so that the bump 16 completely overlaps the second opening. At this point, only the titanium/tungsten alloy conductive layer 14 comes into contact with the pad, thus, effectively reducing the electric impedance introduced by the under bump metal (i.e., the titanium/tungsten alloy conductive layer 14) to the bump 16.

Then, the photoresist layer 15 is removed as shown in FIG. 1(g). Finally, unnecessary portions of the titanium/tungsten alloy conductive layers 13, 14 are removed, leaving only the portions between the bump 16 and the pad 11, as shown in FIG. 1(h).

In this embodiment, the second conductive layer functions as an under bump metal, while the first conductive layer functions as a medial conductive layer to conduct the current, both of which are not limited to be made of a titanium/tungsten alloy. For example, they can be solely made of titanium. Additionally, depending on the different features of the chip (for example, different surface roughness), more than two conductive layers may be formed at locations other than the pad with still only a single layer of under bump metal remaining to allow for a perfect electrical connection between the bump and the pad.

It follows from the above disclosure that, by forming two titanium/tungsten alloy conductive layers 13, 14 over the passivation layer, the conductive structure of this invention is adapted to ensure a sufficient thickness of the conductive layer necessary for the electroplating process to prevent discontinuities and provide stable electric impedance characteristics. Meanwhile, by forming only a single titanium/tungsten alloy conductive layer 14 to come into contact with the pad, this invention can reduce the electric impedance between the pad and the bump to improve the reliability of the conductive structure. The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A conductive structure of a semiconductor integrated circuit which has a pad, and a passivation layer partially overlapping the pad to define a first opening portion having a first lateral dimension, in which the conductive structure is adapted to electrically connect with the pad through the first opening portion, the conductive structure comprising:
a first conductive layer, being formed on the passivation layer to define a second opening portion having a second lateral dimension corresponding to the first opening portion, wherein the second lateral dimension is substantially not smaller than the first lateral dimension; and
a second conductive layer, being substantially formed in the first opening portion for being electrically connected to the pad, wherein the second conductive layer continuously overlaps a periphery portion of the first conductive layer and a periphery portion of the passivation layer.

2. The conductive structure as claimed in claim 1, further comprising a bump being formed on the second conductive layer corresponding to the second opening portion, wherein the bump has a third lateral dimension substantially not smaller than the second lateral dimension.

3. The conductive structure as claimed in claim 2, wherein the bump is made of gold.

4. The conductive structure as claimed in claim 1, wherein at least one of the first conductive layer and the second conductive layer is made of titanium/tungsten alloy.

5. A conductive structure of a semiconductor integrated circuit which has a pad, and a passivation layer partially overlapping the pad, the passivation layer having a periphery portion to define an exposure portion, in which the conductive structure is adapted to electrically connect with the exposure portion, the conductive structure comprising:
at least one medial conductive layer which has a periphery portion formed on the passivation layer, in which the periphery portion of the passivation layer and the periphery portion of the at least one conductive layer subsequently form a substantially stair-shape profile to define a receiving space; and
an under bump metal, being in contact with the exposure portion, and extending to overlap the periphery portion of the passivation layer and the periphery portion of the at least one medial conductive layer.

6. The conductive structure as claimed in claim 5, further comprising a bump being formed on the under bump metal and completely overlapping the whole receiving space.

7. The conductive structure as claimed in claim 6, wherein the bump is made of gold.

8. The conductive structure as claimed in claim 5, wherein at least one of the under bump metal and the at least one media conductive layer is made of titanium/tungsten alloy.

9. A method for forming a conductive structure on a semiconductor integrated circuit which has a pad and a passivation layer partially overlapping the pad to define a first opening portion which has a first lateral dimension, the method comprising the steps of:
(a) forming a second opening portion which has a second lateral dimension by forming a first conductive layer, in which the second opening portion is corresponding to the first opening portion; and
(b) electrically connecting a second conductive layer to the pad through the first opening portion by substantially forming the second conductive layer in the first opening portion to overlap a periphery portion of the first conductive layer and a periphery portion of the passivation layer.

10. The method as claimed in claim 9, wherein after the step (b), the method further comprises the step of forming a bump having a third lateral dimension on the second conductive layer corresponding to the second opening portion, wherein the third lateral dimension is substantially not smaller than the second lateral dimension.
